(19) United States
(12) Patent Application Publication
(10) Pub. No.: US 2016/0284882 A1
(43) Pub. Date: Sep. 29, 2016

(54) Solar Cell

(71) Applicant: LG INNOTEK CO., LTD., Seoul (KR)

(72) Inventor: Jung In Jang, Seoul (KR)

(21) Appl. No.: 15/022,718

(22) PCT Filed: Sep. 17, 2014
(86) PCT No.: PCT/KR2014/008665

§ 371 Date: Mar. 17, 2016

(30) Foreign Application Priority Data
Sep. 17, 2013 (KR) 10-2013-0111659

(51) Int. Cl. H01L 31/0216; H01L 31/0224

(52) U.S. Cl. CPC H01L 31/02167; H01L 31/022441; H01L 31/022433

(57) ABSTRACT

A solar cell, according to an embodiment, comprises: a support substrate; a rear electrode layer formed on the support substrate; a light-absorbing layer foiined on the rear electrode layer; a first buffer layer formed on the light-absorbing layer; a second buffer layer formed on the first buffer layer; and a front electrode layer formed on the second buffer layer, wherein at least one of a second buffer layer or the front electrode layer includes elements of group 13.

### BACKGROUND

1. Field

Embodiments relate to a solar cell.

2. Background

A method of manufacturing a solar cell for photovoltaic power generation will be described. First, a substrate is provided, a rear electrode layer is formed on the substrate, and a plurality of rear electrodes are formed by patterning using a laser.

Then, a light-absorbing layer, a buffer layer, and a high-resistance buffer layer are sequentially formed on the rear electrodes. In order to form the light-absorbing layer, a method of forming a copper-indium-gallium-selenide-based (Cu(In,Ga)Se₂;CIGS-based) light-absorbing layer by simultaneously or individually evaporating copper, indium, gallium, and selenium and a method of forming a metal precursor film and performing a selenization process are widely used. The energy band gap of the light-absorbing layer ranges from about 1 eV to 1.8 eV.

Then, a buffer layer including cadmium sulfide (CdS) is formed on the light-absorbing layer by a sputtering process. The energy band gap of the buffer layer ranges from about 2.2 eV to 2.4 eV.

Then, a through-hole is formed to pass through the light-absorbing layer and the buffer layer. The high-resistance buffer layer may be further formed on the buffer layer and in the through-hole.

Then, a transparent conductive material is stacked on the high-resistance buffer layer, and the through-hole is filled with the transparent conductive material. Accordingly, a transparent electrode layer is formed on the high-resistance buffer layer. For example, a material used as the transparent electrode layer may include aluminum doped zinc oxide and the like. The energy band gap of the transparent electrode layer ranges from about 3.1 eV to 3.3 eV.

Here, the high-resistance buffer layer may be directly in contact with the rear electrode layer exposed by the through-hole. However, there is a problem in that the efficiency of the solar cell is reduced due to the high contact resistance between the high-resistance buffer layer and the rear electrode layer.

Further, the transparent electrode layer requires a high light transmittance and a low sheet resistance in order to improve the efficiency, and thus a transparent electrode layer made of a new material that can satisfy such requirements is required.

Therefore, a solar cell having a new structure that satisfies low contact resistance and high current density is required.

### SUMMARY

Embodiments provide a solar cell having improved light transmittance and photovoltaic conversion efficiency.

A solar cell according to a first embodiment includes a support substrate, a rear electrode layer formed on the support substrate, a light-absorbing layer formed on the rear electrode layer, a first buffer layer formed on the light-absorbing layer, a second buffer layer formed on the first buffer layer, and a front electrode layer formed on the second buffer layer, wherein at least one of a second buffer layer and the front electrode layer includes elements of group 13.

A solar cell according to a second embodiment includes a support substrate, a rear electrode layer formed on the support substrate, a light-absorbing layer formed on the rear electrode layer, a first buffer layer formed on the light-absorbing layer, a second buffer layer formed on the first buffer layer, and a front electrode layer formed on the second buffer layer, wherein at least one layer of the second buffer layer and the front electrode layer is doped with an impurity.

### BRIEF DESCRIPTION OF THE DRAWINGS

Embodiments will be described in detail with reference to the following drawings in which like reference numerals refer to like elements, and wherein:

FIG. 1 is a plan view illustrating a solar cell according to an embodiment;

FIG. 2 is a cross-sectional view illustrating a cross section of the solar cell according to the embodiment; and

FIGS. 3 to 10 are views for describing a method of manufacturing the solar cell according to the embodiment.

### DETAILED DESCRIPTION

In the description of the embodiments, a layer (film), region, pattern, or structure being referred to as being “on/above” or “under/below” a substrate, a layer (film), region, or patterns includes directly being formed thereupon or being an intervening layer. References with respect to “on/above” or “under/below” of each layer will be described based on the drawings.

The thicknesses or sizes of layers (films), regions, patterns, or structures in the drawings may be modified for the sake of clarity and convenience and do not completely reflect actual thicknesses or sizes.

Hereinafter, embodiments of the present invention will be described in detail with reference to the accompanying drawings.

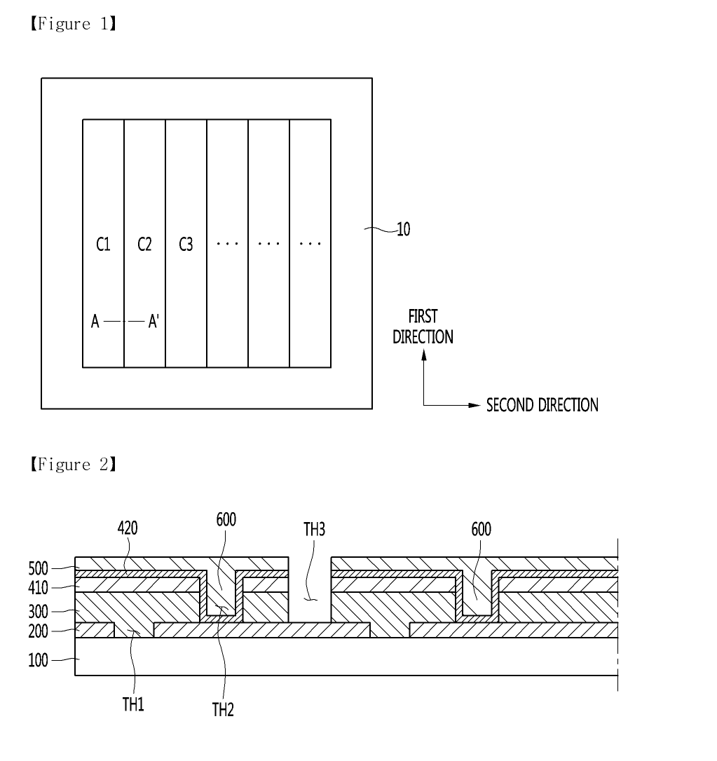

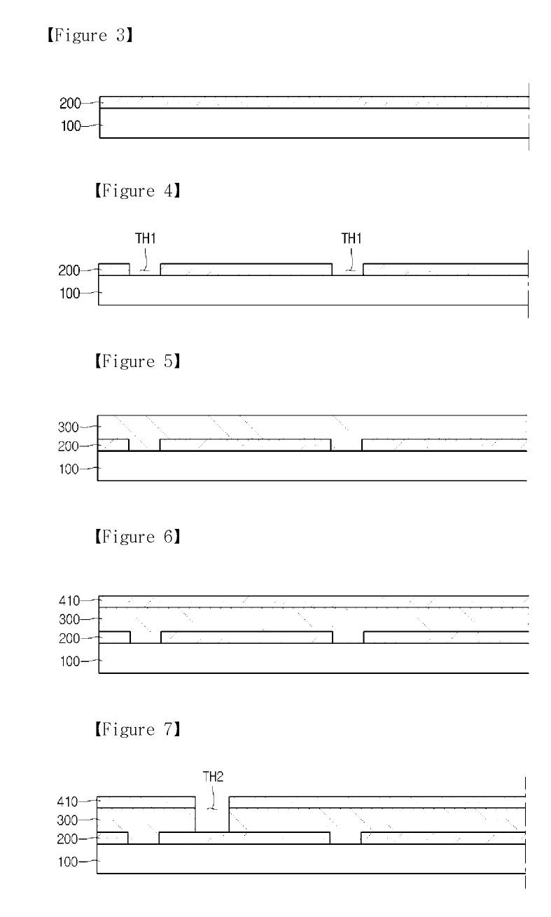

A solar cell according to an embodiment will be described in detail with reference to FIGS. 1 and 2. FIG. 1 is a plan view illustrating the solar cell according to the embodiment, and FIG. 2 is a cross-sectional view illustrating a cross section of the solar cell according to the embodiment.

Referring to FIGS. 1 and 2, the solar cell according to the embodiment includes a support substrate 100, a rear electrode layer 200, a light-absorbing layer 300, a first buffer layer 410, a second buffer layer 420, a front electrode layer 500, and a plurality of connection units 600.

The support substrate 100 has a plate shape and supports the rear electrode layer 200, the light-absorbing layer 300, the first buffer layer 410, the second buffer layer 420, the front electrode layer 500, and the connection units 600.

The support substrate 100 may be an insulator. The support substrate 100 may be a glass substrate, a plastic substrate, or a metal substrate. More specifically, the support substrate 100 may be a soda lime glass substrate. The support substrate 100 may be transparent. The support substrate 100 may be rigid or flexible.

The rear electrode layer 200 is disposed on the support substrate 100. The rear electrode layer 200 is a conductive layer. For example, a material used as the rear electrode layer 200 may include a metal such as molybdenum and the like.

Further, the rear electrode layer 200 may include two or more layers. In this case, each of the layers may be formed of the same metal or different metals.

First through-holes TH1 are formed in the rear electrode layer 200. The first through-holes TH1 are open regions which expose an upper surface of the support substrate 100. In a plan view, each of the first through-holes TH1 may have a shape which extends in a first direction.

A width of each of the first through-holes TH1 may range from about 80 μm to about 200 μm.

The rear electrode layer 200 is divided into a plurality of rear electrodes by the first through-holes TH1. That is, the rear electrodes are defined by the first through-holes TH1.

The rear electrodes are spaced apart from each other by the first through-holes TH1. The rear electrodes are disposed in a stripe pattern.

Alternatively, the rear electrodes may be disposed in a matrix form. In this case, in a plan view, the first through-holes TH1 may be formed in a lattice pattern.

The light-absorbing layer 300 is disposed on the rear electrode layer 200. Further, the first through-holes TH1 are filled with a material included in the light-absorbing layer 300.

The light-absorbing layer 300 includes an I-III-VI group based compound. For example, the light-absorbing layer 300 may have a copper-indium-gallium-selenide-based (Cu(In,Ga)Se₂;CIGS-based) crystal structure, a copper-indium-selenide-based crystal structure, or a copper-gallium-selenide-based crystal structure.

The energy band gap of the light-absorbing layer 300 may range from about 1 eV to 1.8 eV.

Then, the buffer layer is disposed on the light-absorbing layer 300. The buffer layer is directly in contact with the light-absorbing layer 300.

The buffer layer may include the first buffer layer 410 and the second buffer layer 420. Specifically, the first buffer layer 410 is formed on the light-absorbing layer 300, and the second buffer layer 420 is formed on the first buffer layer 410.

The first buffer layer 410 and the second buffer layer 420 may include different materials.

The first buffer layer 410 may include CdS or Zn(O,S). Further, the second buffer layer 420 may include zinc oxide (ZnO).

Second through-holes TH2 may be formed on the buffer layer. Specifically, the second through-holes TH2 are formed on the first buffer layer 410, and the second buffer layer 420 may be formed on the first buffer layer 410 while filling the inside of each of the second through-holes TH2.

The second through-holes TH2 are open regions which expose the upper surface of the support substrate 100 and an upper surface of the rear electrode layer 200. Accordingly, the second buffer layer 420 formed inside the second through-holes TH2 may be directly in contact with the rear electrode layer 200 exposed by the second through-holes TH2.

In a plan view, each of the second through-holes TH2 may have a shape which extends in a direction. A width of each of the second through-holes TH2 may range from about 80 μm to about 200 μm, but the present invention is not limited thereto.

The buffer layer, that is, the first buffer layer 410 and the second buffer layer 420, are defined as a plurality of buffer layers by the second through-holes TH2.

The second buffer layer 420 may further include elements of group 13 rather than zinc oxide. Specifically, the second buffer layer 420 may include at least one element of group 13 of aluminum (Al), gallium (Ga), and boron (B). More specifically, the second buffer layer 420 may include at least one element of group 13 of aluminum and gallium.

For example, the second buffer layer 420 may be doped with an impurity. For example, the second buffer layer 420 may be doped with a small amount of compound containing elements of group 13.

Specifically, the second buffer layer 420 may be doped with compounds containing at least one of aluminum and gallium. For example, the second buffer layer 420 may be doped with metal oxides. Specifically, the second buffer layer 420 may be doped with an oxide such as Al₂O₃, B₂O₃, Ga₂O₃, or the like.

A small amount of an element of group 13, that is, aluminum or gallium, may be added to or doped on the second buffer layer 420. The aluminum or gallium may reduce the contact resistance of the second buffer layer 420.

That is, the second buffer layer 420 is directly in contact with the rear electrode layer 200 exposed by the second through-holes TH2, and thus a contact resistance may occur. In this case, the high contact resistance may occur due to a difference between physical properties of zinc oxide and the rear electrode layer.

The high contact resistance influences the efficiency of the solar cell and may be an overall cause for decreasing efficiency of the solar cell.

Therefore, a small amount of element of group 13 are added to or doped in the second buffer layer 420 in contact with the rear electrode layer 200, and thus a contact resistance may be reduced. Therefore, in the solar cell according to the embodiment, the contact resistance of the rear electrode layer 200 and the second buffer layer 420 may be reduced, and thus an overall efficiency of the solar cell may be improved.

The front electrode layer 500 is disposed on the buffer layer. Specifically, the front electrode layer 500 is disposed on the second buffer layer 420. The front electrode layer 500 is transparent and a conductive layer. Further, the resistance of the front electrode layer 500 is higher than that of the rear electrode layer 500.

The front electrode layer 500 includes an oxide. For example, the front electrode layer 500 includes zinc oxide (ZnO). Further, the front electrode layer 500 may further include elements of group 13 rather than the zinc oxide. Specifically, the front electrode layer 500 may include at least one element of group 13 of aluminum (Al), gallium (Ga), and boron (B). More specifically, the front electrode layer 500 may include at least one element of group 13 of aluminum and gallium.

A small amount of element of group 13, that is, aluminum or gallium, may be added to the front electrode layer 500.

For example, the front electrode layer 500 may be doped with an impurity. For example, the front electrode layer 500 may be doped with a small amount of compounds containing elements of group 13.

Specifically, the front electrode layer 500 may be doped with compounds containing at least one of aluminum and gallium. For example, the front electrode layer 500 may be doped with metal oxides. Specifically, the front electrode layer 500 may be doped with an oxide such as Al₂O₃, Ga₂O₃, or the like.

Accordingly, the front electrode layer 500 may include zinc oxide (Al doped ZnO;AZO) in which aluminum is doped or zinc oxide (Ga doped ZnO;GZO) in which gallium is doped.

As the aluminum or gallium is added to or doped in the front electrode layer 500, the light transmittance of the front electrode layer 500 may be improved and the sheet resistance may be reduced.

That is, the front electrode layer 500 which is a layer formed at the outermost periphery of the solar cell serves as the light incident surface. Accordingly, the front electrode layer 500 requires a high light transmittance and a low sheet resistance. That is, as the light transmittance and the sheet resistance are variables which are closely related to the current density (JSC) and efficiency of the solar cell, the efficiency of the solar cell may be changed depending on the light transmittance and the sheet resistance.

Therefore, in the solar cell according to the embodiment, as a small amount of element of group 13 is added to or doped in the front electrode layer 500, the light transmittance may be improved, and the sheet resistance may be reduced. Therefore, in the solar cell according to the embodiment, the current density may be improved, and thus an overall efficiency of the solar cell may be improved.

At least one layer of the second buffer layer 420 and the front electrode layer 500 may include elements of group 13. For example, both of the second buffer layer 420 and the front electrode layer 500 may include elements of group 13. Specifically, both of the second buffer layer 420 and the front electrode layer 500 may include at least one element of aluminum and gallium.

In this case, the second buffer layer 420 and the front electrode layer 500 may include the same elements of group 13 or different elements of group 13. When including the same elements of group 13, the second buffer layer 420 and the front electrode layer 500 may include aluminum or gallium.

The front electrode layer 500 includes the connection units 600 located inside the second through-holes TH2.

Third through-holes TH3 are formed in the first buffer layer 410, the second buffer layer 420, and the front electrode layer 500. The third through-holes TH3 may pass through a portion or both of the first buffer layer 410 and the second buffer layer 420 and the front electrode layer 500. That is, the third through-holes TH3 may expose the upper surface of the rear electrode layer 200.

The third through-holes TH3 are formed adjacent to the second through-holes TH2. More specifically, the third through-holes TH3 are disposed next to the second through-holes TH2. That is, in a plan view, the third through-holes TH3 are disposed next to the second through-holes TH2 side by side. Each of the third through-holes TH3 may have a shape which extends in the first direction.

The third through-holes TH3 pass through the front electrode layer 500. More specifically, the third through-holes TH3 may pass through a portion or all of the light-absorbing layer 300, the first buffer layer 410, and the second buffer layer 420.

The front electrode layer 500 is divided into a plurality of front electrodes by the third through-holes TH3. That is, the front electrodes are defined by the third through-holes TH3.

Each of the front electrodes has a pattern corresponding to each of the rear electrodes. That is, the front electrodes are disposed in a stripe pattern. Alternatively, the front electrodes may be disposed in a matrix form.

Further, a plurality of solar cells C1, C2, etc. are defined by the third through-holes TH3. More specifically, the solar cells C1, C2, etc. are defined by the second through-holes TH2 and the third through-holes TH3. That is, the solar cell according to the embodiment is divided into the solar cells C1, C2, etc. by the second through-holes TH2 and the third through-holes TH3. Further, the solar cells C1, C2, etc. are connected to each other in a second direction crossing the first direction. That is, a current may flow in the second direction through the solar cells C1, C2, etc.

That is, a solar cell panel 10 includes the support substrate 100 and the solar cells C1, C2, etc. The solar cells C1, C2, etc. are disposed on the support substrate 100 and are spaced apart from each other. Further, the solar cells C1, C2, etc. are connected to each other in series by the connection units 600.

The connection units 600 are disposed inside the second through-holes TH2. The connection units 600 extend downward from the front electrode layer 500, and are connected to the rear electrode layer 200. For example, the connection units 600 extend from a front electrode of a first cell C1 and are connected to a rear electrode of a second cell C2.

Therefore, the connection units 600 connect the adjacent solar cells. More specifically, the connection units 600 connect the front electrode and the rear electrode included in each of the adjacent solar cells.

The connection unit 600 is integrally formed with the front electrode layer 500. That is, a material used as the connection unit 600 is the same as the material used as the front electrode layer 500.

As described above, in the solar cell according to the embodiment, impurities including elements of group 13 are added to or doped on the second buffer layer or the front electrode layer. Accordingly, the light transmittance of the front electrode layer may be improved, and the sheet resistance may be reduced. Further, the contact resistance between the second buffer layer and the rear electrode layer may be reduced.

Accordingly, since the solar cell according to the embodiment has an improved current density and a low contact resistance, the overall efficiency of the solar cell may be improved.

Hereinafter, the present invention will be described in more detail through an embodiment. Such an embodiment is merely presented as an example for describing the present invention in more detail. Therefore, the present invention is not limited to the embodiment.

Embodiment

After a rear electrode layer including molybdenum is formed on a glass or plastic support substrate, the rear electrode layer was divided into a plurality of rear electrodes by patterning the rear electrode layer. Then, a light-absorbing layer was formed on the rear electrode layer, and a first buffer layer and a second buffer layer were formed on the light-absorbing layer.

At this point, the second buffer layer was doped with aluminum oxide (Al₂O₃) or gallium oxide (Ga₂O₃) by a vacuum deposition method.

Then, a solar cell was manufactured by forming a front electrode layer on the second buffer layer. At this point, the front electrode layer was doped with aluminum oxide (Al₂O₃) or gallium oxide (Ga₂O₃) by a vacuum deposition method.

### COMPARATIVE EXAMPLE

A solar cell was manufactured in the same manner as the embodiment except that a second buffer layer and a front electrode layer were not doped.

Results

The characteristics, current density, and contact resistance of the front electrode layers of the solar cells according to the embodiment and the comparative example have been measured and compared, and the characteristics are as the following Table 1.

TABLE 1

| | | | | | | | Contact |
|---|---|---|---|---|---|---|---|
| | | | | | | | resistance of |
| | | | Front electrode layer characteristics | | | | second buffer |
| First | | Front | Sheet | Transmittance | Transmittance | | layer and rear |
| buffer | Second | electrode | resistance | (%) | (%) | JSC | electrode layer |
| layer | buffer layer | layer | (□/Ω) | (400~800 nm) | (800~1200 nm) | (mA/cm²) | (Ω) |
| CdS | i-ZnO | AZO | 13.5 | 89.0 | 82.0 | 31.5 | 1.85 |
| | | GAZO | 11.5 | 89.0 | 75.0 | 31 | 2.32 |
| | B doped | BZO | 9.7 | 85.8 | 91.3 | 27.8 | 2.51 |
| | ZnO | | | | | | |
| | Al₂O₃ doped | AZO | 16.5 | 89.6 | 83.2 | 34.5 | 1.45 |
| | ZnO | | | | | | |
| | Ga₂O₃ doped | GAZO | 9.7 | 91.3 | 86.5 | 35.8 | 1.20 |
| | ZnO | | | | | | |
| Zn(O,S) | i-ZnO | AZO | 13.5 | 89.0 | 82.0 | 31 | 1.98 |
| | | GAZO | 11.5 | 89.0 | 75.0 | 30.2 | 2.37 |
| | B doped | BZO | 11.0 | 87.4 | 91.6 | 28.9 | 2.55 |
| | ZnO | | | | | | |
| | Al₂O₃ doped | AZO | 16.7 | 89.7 | 83.5 | 34.2 | 1.75 |
| | ZnO | | | | | | |
| | Ga₂ O₃ doped | GAZO | 10.1 | 91.5 | 86.8 | 36 | 1.38 |
| | ZnO | | | | | | |

Referring to Table 1, it may be seen that, when the second buffer layer and the front electrode layer are doped with elements of group 13, that is, boron, aluminum, or gallium, the light transmittance of the front electrode layer is improved and the sheet resistance is reduced compared to the case of not doping.

Further, it may be seen that the current density is also improved in the case of doping compared to the case of not doping.

Therefore, in the solar cell according to the embodiment, it may be seen that at least one layer of the second buffer layer and the front electrode layer is doped with at least one element of group 13 of boron, aluminum, and gallium and thus the overall efficiency of the solar cell can be improved.

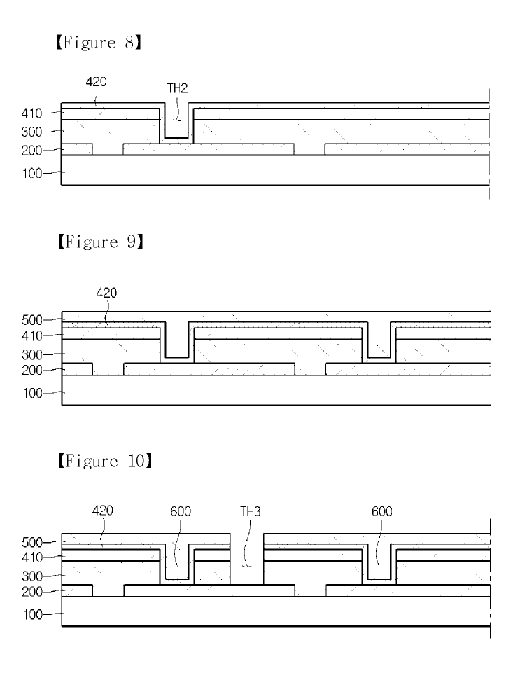

Hereinafter, a method of manufacturing the solar cell according to the embodiment will be described with reference to FIGS. 3 to 10. FIGS. 3 to 10 are views for describing the method of manufacturing the solar cell according to the embodiment.

First, referring to FIG. 3, a rear electrode layer 200 is formed on a support substrate 100.

Then, referring to FIG. 4, first through-holes TH1 are formed by patterning the rear electrode layer 200. Accordingly, a plurality of rear electrodes are formed on the support substrate 100. The rear electrode layer 200 is patterned by a laser.

The first through-holes TH1 may expose an upper surface of the support substrate 100 and may each have a width in a range from about 80 μm to about 200 μm.

Further, an additional layer such as a diffusion barrier film and the like may be interposed between the support substrate 100 and the rear electrode layer 200, and in this case, the first through-holes TH1 expose an upper surface of the additional layer.

Then, referring to FIG. 5, a light-absorbing layer 300 is formed on the rear electrode layer 200. The light-absorbing layer 300 may be formed by a sputtering process or an evaporation method.

For example, in order to form the light-absorbing layer 300, a method of forming the copper-indium-gallium-selenide-based (Cu(In,Ga)Se₂;CIGS-based) light-absorbing layer 300 by simultaneously or individually evaporating copper, indium, gallium, and selenium and a method of forming the light-absorbing layer 300 by forming a metal precursor film and performing a selenization process are widely used.

To describe the selenization process after the forming of the metal precursor film in detail, a metal precursor film is formed on the rear electrode layer 200 by a sputtering process in which a copper target, an indium target, and a gallium target are used.

Then, the copper-indium-gallium-selenide-based (Cu(In,Ga)Se₂;CIGS-based) light-absorbing layer 300 is formed by performing a selenization process on the metal precursor film.

Alternatively, a sputtering process in which a copper target, an indium target, and a gallium target are used and the selenization process may be performed simultaneously.

Alternatively, a CIS-based or CIG-based light-absorbing layer 300 may be formed by a sputtering process in which only a copper target and an indium target are used or by a sputtering process in which a copper target and a gallium target are used and the selenization process.

Then, referring to FIG. 6, cadmium sulfide is deposited by a sputtering process, a chemical bath deposition (CBD) method, or the like, and the first buffer layer 410 is formed.

Then, referring to FIG. 7, second through-holes TH2 are formed by removing portions of the light-absorbing layer 300 and the first buffer layer 410.

The second through-holes TH2 may be formed by a mechanical device including a tip and the like or a laser device and the like.

For example, the light-absorbing layer 300 and the buffer layers may be patterned by a tip having a width in a range from about 40 μm to about 180 μm. Further, the second through-holes TH2 may be formed by a laser having a wavelength in a range from about 200 nm to about 600 nm.

In this case, a width of each of the second through-holes TH2 may range from about 100 μm to about 200 μm. Further, the second through-holes TH2 are formed to expose a portion of an upper surface of the rear electrode layer 200.

Then, referring to FIG. 8, a second buffer layer 420 may be formed on the first buffer layer 410. The second buffer layer 420 may be formed by depositing zinc oxide doped with aluminum or gallium by a deposition process and the like.

The order of forming the second buffer layer 420 and the second through-holes TH2 may be changed. That is, after the second buffer layer 420 is formed first, the second through-holes TH2 may be formed.

Then, referring to FIG. 9, a front electrode layer 500 is formed by depositing a transparent conductive material on the second buffer layer 420.

The front electrode layer 500 may be formed by depositing zinc oxide doped with aluminum or gallium by a deposition process or the like.

Specifically, the front electrode layer 500 may be formed by depositing zinc oxide doped with aluminum or gallium in an inert gas atmosphere that does not contain oxygen.

The front electrode layer 500 may be formed by depositing zinc oxide doped with aluminum or gallium by a radio frequency (RF) sputtering method which is a depositing method using a ZnO target or by a reactive sputtering method using a Zn target.

Then, referring to FIG. 10, third through-holes TH3 are formed by removing portions of the light-absorbing layer 300, the first buffer layer 410, the second buffer layer 420, and the front electrode layer 500. Accordingly, a plurality of front electrodes, a first cell C1, a second cell C2, and a third cells C3 are defined by patterning the front electrode layer 500. A width of each of the third through-holes TH3 may range from about 80 μm to about 200 μm.

In the solar cell according to the embodiment, a second buffer layer and a front electrode layer are doped with elements of group 13.

That is, in the solar cell according to the embodiment, the second buffer layer and the front electrode layer can be formed by doping with a compound containing at least one of boron, aluminum, and gallium.

Accordingly, the contact resistance of the second buffer layer and the rear electrode layer can be reduced. Further, the light transmittance of the front electrode layer can be improved, and the sheet resistance can be reduced.

That is, as the composition of the second buffer layer and the front electrode layer is changed, the contact resistance and the sheet resistance can be reduced, and the current density can be improved.

Therefore, the solar cell according to the embodiment can have an overall improved photovoltaic conversion efficiency.

The features, structures, effects, and the like described in the above-described embodiments include at least one embodiment of the present invention, but the present invention is not limited only to one embodiment. Further, the features, structures, effects, and the like illustrated in each embodiment may be combined or modified to other embodiments by those skilled in the art. Therefore, contents related to the combination or the modification should be interpreted to be included in the scope of the invention.

In addition, while the present invention has been particularly described with reference to exemplary embodiments, the present invention is not limited thereto. It will be understood by those skilled in the art that various modifications and applications, which are not illustrated in the above, may be made without departing from the spirit and scope of the present invention. For example, each of components illustrated in the embodiments may be modified and made. It should be interpreted that differences related to these modifications and applications are included in the scope of the invention defined in the appended claims.

1. A solar cell comprising:
a support substrate;
a rear electrode layer formed on the support substrate;
a light-absorbing layer formed on the rear electrode layer;
a first buffer layer formed on the light-absorbing layer;
a second buffer layer formed on the first buffer layer; and
a front electrode layer formed on the second buffer layer,
wherein at least one layer of the second buffer layer and the front electrode layer includes elements of group 13.

2. The solar cell according to claim 1, wherein the elements of group 13 include at least one element of aluminum (Al), gallium (Ga), and boron (B).

3. The solar cell according to claim 1, wherein the second buffer layer is directly in contact with the rear electrode layer.

4. The solar cell according to claim 3, wherein the second buffer layer and the front electrode layer include at least one element of aluminum, boron, and gallium.

5. The solar cell according to claim 4, wherein the second buffer layer and the front electrode layer are doped with an oxide including at least one of Al₂O₃, B₂O₃, and Ga₂O₃.

6. The solar cell according to claim 3, wherein the second buffer layer and the front electrode layer include the same elements of group 13.

7. The solar cell according to claim 3, wherein the second buffer layer and the front electrode layer include different elements of group 13.

8. The solar cell according to claim 1, wherein the first buffer layer and the second buffer layer include different materials.

9. A solar cell comprising:
a support substrate;
a rear electrode layer formed on the support substrate;
a light-absorbing layer formed on the rear electrode layer;
a first buffer layer formed on the light-absorbing layer;
a second buffer layer formed on the first buffer layer; and
a front electrode layer formed on the second buffer layer,
wherein at least one layer of the second buffer layer and the front electrode layer is doped with an impurity.

10. The solar cell according to claim 9, wherein the impurity includes elements of group 13.

11. The solar cell according to claim 10, wherein the elements of group 13 include at least one element of gallium and aluminum.

12. The solar cell according to claim 9, wherein at least one layer of the second buffer layer and the front electrode layer is doped with an impurity including at least one of Al₂O₃, B₂O₃, and Ga₂O₃.

13. The solar cell according to claim 12, wherein:
the second buffer layer and the front electrode layer is doped with an impurity of Al₂O₃, B₂O₃, or Ga₂O₃; and
the second buffer layer and the front electrode layer is doped with the same impurity.

14. The solar cell according to claim 12, wherein:
the second buffer layer and the front electrode layer is doped with an impurity of Al₂O₃, B₂O₃, or Ga₂O₃; and
the second buffer layer and the front electrode layer is doped with different impurities.

15. The solar cell according to claim 9, wherein the first buffer layer and the second buffer layer include different materials.

16. The solar cell according to claim 9, wherein the second buffer layer is directly in contact with the rear electrode layer.

17. The solar cell according to claim 1, wherein the first buffer layer includes CdS or Zn(O,S).

18. The solar cell according to claim 9, wherein the first buffer layer includes CdS or Zn(O,S).
